(19) United States
(12) Patent Application Publication
(10) Pub. No.: US 2021/0400823 A1
(43) Pub. Date: Dec. 23, 2021

(54) DISPLAY FRAME WITH MULTIPLE SLIDE-IN PANELS

(71) Applicant: Will Uebelacker, Portland, OR (US)

(72) Inventor: Will Uebelacker, Portland, OR (US)

(21) Appl. No.: 17/395,886

(22) Filed: Aug. 6, 2021

Related U.S. Application Data
(60) Provisional application No. 63/040,757, filed on Jun. 18, 2020.

(51) Int. Cl. H05K 5/00

(52) U.S. Cl. CPC H05K 5/0021; H05K 5/0017

(57) ABSTRACT

A display frame may be constructed and arranged to receive and display multiple decorative panels, such as machine cut panels, to create a 3-dimensional shadowbox effect when viewed. The display frame may include a plurality of frame portions, each frame portion defining a plurality of channels into which a display panel may be disposed. At least a portion of the plurality of frame portions may include a top frame which may define through channels such that displays may be slid through the top frame and into the remaining plurality of channels such that various display panels may be secured by the frame.

### CROSS-REFERENCE TO RELATED APPLICATIONS

This application claims the benefit of U.S. Provisional Application Ser. No. 63/040,757 filed Jun. 18, 2020.

### TECHNICAL FIELD

The embodiments generally relate to display frames.

### BACKGROUND

Display frames may include a backing substrate for supporting an image or center panel, such as a photo, a transparent top substrate over the center panel, such as glass, to sandwich the display image between the backing substrate and the top substrate, and a frame to secure the combination of the top substrate, display image, and backing substrate therein. Display frames may hold a display single images or, occasionally, multiple images in a “collage” style arrangement.

### SUMMARY OF THE INVENTION

This summary is provided to introduce a variety of concepts in a simplified form that is further disclosed in the detailed description of the embodiments. This summary is not intended to identify key or essential inventive concepts of the claimed subject matter, nor is it intended for determining the scope of the claimed subject matter.

The embodiments described herein provide a display frame constructed and arranged to receive multiple displays, such as machine cut panels to create a 3-dimensional shadowbox effect when viewed. The display frame may include a plurality of frame portions, each frame portion defining a plurality of channels into which a display may be disposed. At least a portion of the plurality of frame portions may include a top frame which may define through channels such that displays may be slid through the top frame and into the remaining plurality of channels such that the display is secured by the frame.

Other illustrative variations within the scope of the invention will become apparent from the detailed description provided hereinafter. The detailed description and enumerated variations, while disclosing optional variations, are intended for purposes of illustration only and are not intended to limit the scope of the invention.

### BRIEF DESCRIPTION OF THE DRAWINGS

A complete understanding of the present embodiments and the advantages and features thereof will be more readily understood by reference to the following detailed description when considered in conjunction with the accompanying drawings wherein:

FIG. 1 illustrates a perspective view of a display frame, according to some embodiments;

FIG. 2 illustrates a front view of a display frame, according to some embodiments;

FIG. 3 illustrates a cross-sectional view of a display frame, according to some embodiments;

FIG. 4 illustrates a cross-sectional view of a display frame, according to some embodiments;

FIG. 5 illustrates a perspective view of a display frame receiving a plurality of displays therein, according to some embodiments;

FIG. 6 illustrates an exploded perspective view of a display frame, according to some embodiments; and

FIG. 7 illustrates a cross sectional view of a display frame, according to some embodiments.

### DETAILED DESCRIPTION

The specific details of the single embodiment or variety of embodiments described herein are to the described apparatus. Any specific details of the embodiments are used for demonstration purposes only, and no unnecessary limitations or inferences are to be understood therefrom.

Before describing in detail exemplary embodiments, it is noted that the embodiments reside primarily in combinations of components and procedures related to the apparatus. Accordingly, the apparatus components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

The specific details of the single embodiment or variety of embodiments described herein are set forth in this application. Any specific details of the embodiments are used for demonstration purposes only, and no unnecessary limitation or inferences are to be understood therefrom. Furthermore, as used herein, relational terms, such as “first” and “second,” “top” and “bottom,” and the like, may be used to distinguish one entity or element from another entity or element without necessarily requiring or implying any physical or logical relationship, or order between such entities or elements.

In general, the embodiments provided herein relate to a display frame having a top frame, first side frame, second side frame, and bottom frame. Each of the first side frame, second side frame, and bottom side frame may define a respective first, second, and third plurality of channels therein. The top frame may define a plurality of through slots constructed and arranged to allow at least one, or a plurality, of display panels to pass therethrough and slidably mate with the first, second, and third plurality of channels. The first side frame, second side frame, bottom side frame, and top frame may be constructed and arranged to mechanically connect to one another such that the first, second, and third plurality of channels align with the plurality of through slots defined by the top frame. The frame may be made of any appropriate material such as, but not limited to, plastic, wood, metal, or the like.

Display panels may be any rigid or semi-rigid panel capable of supporting an image thereon, such as a photo. According to some variations, display panels may be laser or machine cut panels defining a silhouette of a decorative element, or a plurality of silhouettes combinable to create a three-dimensional shadowbox style display. According to some variations, individual display panels may be partially translucent or partially transparent and may include only a portion of a decorative image thereon such that when multiple display panels are disposed within the display frame a composite image may be formed from the combination of various portions of decorative images on individual display panels. As a non-limiting example, a plurality of glass display panels may include, each individually, a portion of a composite decorative image such that when assembled within the display frame, create a 3-dimensional shadowbox effect of the decorative image being displayed.

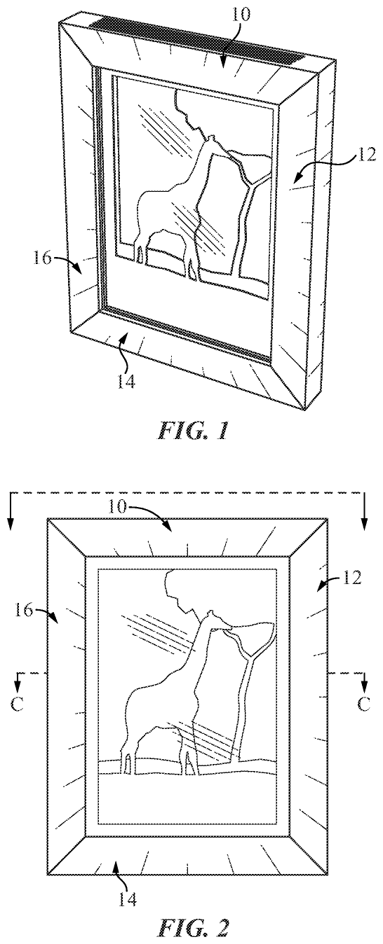

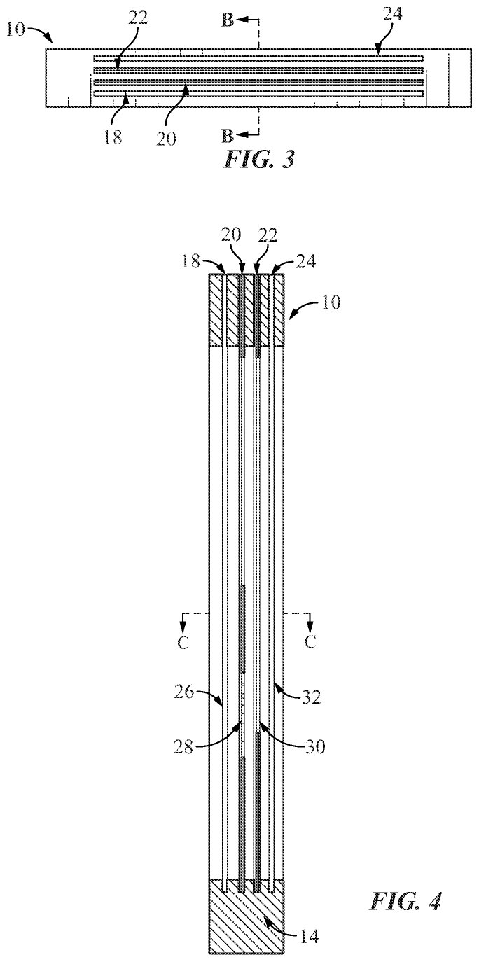

FIGS. 1 and 2 illustrates a variation of a display frame including a top frame 10, a first side frame 12, a second side frame 16, and a bottom frame 14. The top frame 10, first side frame 12, second side frame 16, and bottom frame 14 may be connected to frame and enclose at least one display panel. FIG. 3 indicates top-down view BB and cross-sectional view CC, as best seen in FIG. 4 and FIG. 7 respectively.

FIG. 3 illustrates a top-down view of a display frame including top frame 10. Top frame 10 may define a plurality of through-slots 18, 20, 22, and 24. While the various figures depict four through-slots and channels within the portions of the frame, any number of through-slots and channels are considered part of the invention.

FIG. 4 illustrates a cross sectional view of a display frame according to BB as seen in FIG. 2, including a top frame 10 defining a plurality of through slots 18, 20, 22, and 24. The display frame may include bottom frame 14 defining a third plurality of channels 54, 56, 58, and 60. A first display panel 26 may be disposed within the display frame by passing the first display panel 26 through through-slot 18 and into channel 54. Additional display panels 28, 30, and 32 may be seated within the display frame similarly. Display panels may include decorative elements 50, 52 distributed across the various display panels. In some variations, display panels may be entirely transparent, translucent, or opaque. In some variations, display panels may be partially transparent, translucent, or opaque.

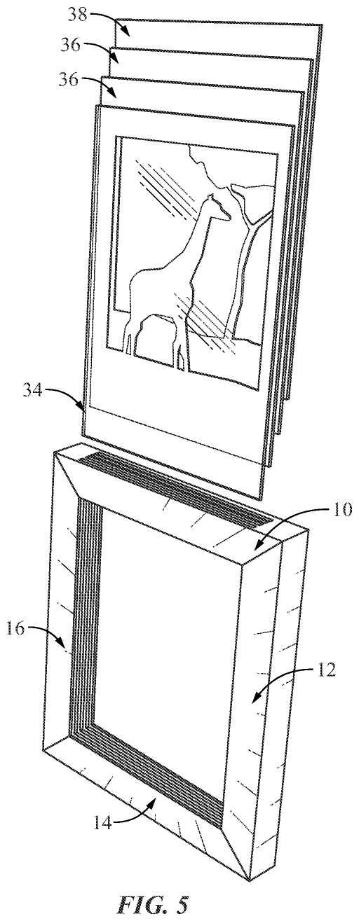

FIG. 5 illustrates a perspective view of a display frame receiving a plurality of display panels therein. The display frame may include top frame 10, first side frame 12, second side frame 16, and bottom frame 14 that may receive and hold various display panels 34, 36, and 38 depicting various decorative elements 50, 52. According to some variation, the rear-most display panel 38 may function as a structural backing for the display frame. According to some variations, the frontmost display panel 34 may be a transparent material such as glass.

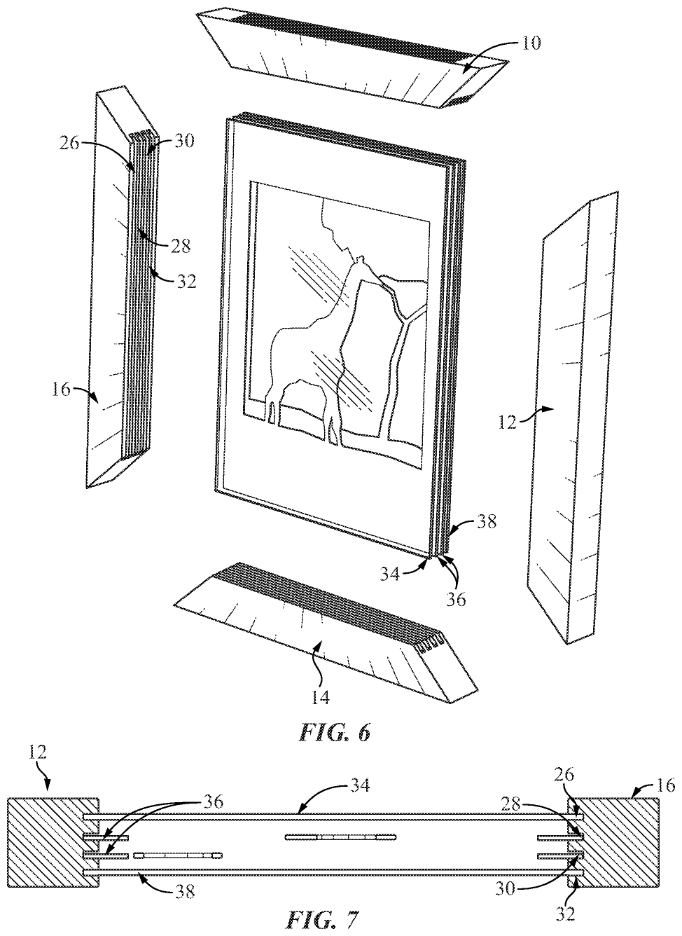

FIG. 6 illustrates an exploded perspective view of a display frame including a top frame 10, first side frame 12, second side frame 16, and bottom frame 14 that may receive and hold various display panels 34, 36, and 38 depicting various decorative elements. Each of the first side frame 12, second side frame 16, and bottom frame 14 may define respective pluralities of channels as best seen on the second side frame 16 defining a second plurality of channels 26, 28, 30, and 32.

FIG. 7 illustrates a top-down cross-sectional view of a display frame according to CC as seen in FIG. 2. The first side frame 12 and second side frame 16 may be constructed and arranged to secure a plurality of display panels 34, 36, and 38 within the first plurality of channels 70, 72, 74, 76 and the second plurality of channels 26, 28, 30, and 32.

The following description of variants is only illustrative of components, elements, acts, products, and methods considered to be within the scope of the invention and are not in any way intended to limit such scope by what is specifically disclosed or not expressly set forth. The components, elements, acts, products, and methods as described herein may be combined and rearranged other than as expressly described herein and are still considered to be within the scope of the invention.

According to variation 1, a display frame with multiple slide-in panels may include a top frame defining a plurality of through-slots; a first side frame defining a first plurality of channels; a second side frame defining a second plurality of channels; and a bottom frame defining a third plurality of channels. The display frame may further include a plurality of display panels each displaying a unique decorative element, the plurality of display panels being constructed and arranged to be seated at least partially within the plurality of through-slots, the first plurality of channels, the second plurality of channels, and the third plurality of channels such that a composite display image is formed by the unique decorative elements.

Variation 2 may include display frame with multiple slide-in panels as in variation 1, wherein the plurality of display panels includes a first display panel, a second display panel, a third display panel, and a fourth display panel.

Variation 3 may include display frame with multiple slide-in panels as in any of variations 1 through 2, wherein the first display panel is transparent.

Variation 4 may include display frame with multiple slide-in panels as in any of variations 1 through 3, wherein the fourth display panel is opaque.

Variation 5 may include display frame with multiple slide-in panels as in any of variations 1 through 4, wherein the composite display image includes a three-dimensional shadowbox appearance.

Variation 6 may include display frame with multiple slide-in panels as in any of variations 1 through 5, wherein each of the unique decorative elements includes a laser-cut silhouette.

Variation 7 may include display frame with multiple slide-in panels as in any of variations 1 through 6, wherein each of the unique decorative elements includes a machine-cut silhouette.

Variation 8 may include display frame with multiple slide-in panels as in any of variations 1 through 7, wherein each of the unique decorative elements include an engraving.

Variation 9 may include display frame with multiple slide-in panels as in any of variations 1 through 8, wherein each of the unique decorative elements include a printed image.

According to variation 10, a display frame with multiple slide-in panels may include a generally rectangular top frame defining four through-slots; a generally rectangular first side frame defining a first set of four channels; a generally rectangular second side frame defining a second set of four channels; and a generally rectangular bottom frame defining a third set of four channels. The display frame may further include a plurality of generally rectangular display panels including a first, second, third, and fourth display panel, each including a unique decorative element, the plurality of display panels being constructed and arranged to be seated at least partially within the plurality of through-slots, the first set of four channels, the second set of four channels, and the third set of four channels such that a composite display image is formed by the unique decorative elements.

Variation 11 may include display frame with multiple slide-in panels as in variation 10, wherein the first display panel is glass.

Variation 12 may include display frame with multiple slide-in panels as in any of variations 10 through 11, wherein the fourth display panel is opaque.

Variation 13 may include display frame with multiple slide-in panels as in any of variations 10 through 12, wherein the composite display image includes a three-dimensional shadowbox appearance.

Variation 14 may include display frame with multiple slide-in panels as in any of variations 10 through 13, wherein each of the unique decorative elements includes a laser-cut decorative silhouette.

Variation 15 may include display frame with multiple slide-in panels as in any of variations 10 through 14, wherein each of the unique decorative elements includes a machine-cut decorative silhouette.

Variation 16 may include display frame with multiple slide-in panels as in any of variations 10 through 15, wherein each of the unique decorative elements include an engraving.

Variation 17 may include display frame with multiple slide-in panels as in any of variations 10 through 16, wherein each of the unique decorative elements include a printed image.

According to variation 18, a display frame with multiple slide-in panels may include a generally rectangular top frame defining four through-slots; a generally rectangular first side frame defining a first set of four channels; a generally rectangular second side frame defining a second set of four channels; and a generally rectangular bottom frame defining a third set of four channels. The display frame may further include a first display panel including a first decorative element, the first display panel being removably seated within the first, second, and third set of four channels; a second display panel including a second decorative element, the second display panel being removably seated within the first, second, and third set of four channels; a third display panel including a third decorative element, the third display panel being removably seated within the first, second, and third set of four channels; and a fourth display panel including a fourth decorative element, the fourth display panel being removably seated within the first, second, and third set of four channels. The first, second, third, and fourth decorative elements may form a composite display.

Variation 19 may include display frame with multiple slide-in panels as in variation 18, wherein each of the unique decorative elements includes at least one of a machine-cut or laser-cut decorative silhouette.

Variation 20 may include display frame with multiple slide-in panels as in any of variations 18 through 19, wherein each of the unique decorative elements includes images.

Many different embodiments have been disclosed herein, in connection with the above description and the drawings. It will be understood that it would be unduly repetitious and obfuscating to describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

An equivalent substitution of two or more elements can be made for any one of the elements in the claims below or that a single element can be substituted for two or more elements in a claim. Although elements can be described above as acting in certain combinations and even initially claimed as such, it is to be expressly understood that one or more elements from a claimed combination can in some cases be excised from the combination and that the claimed combination can be directed to a subcombination or variation of a subcombination.

It will be appreciated by persons skilled in the art that the present embodiment is not limited to what has been particularly shown and described hereinabove. A variety of modifications and variations are possible in light of the above teachings without departing from the following claims.

What is claimed is:

1. A display frame with multiple slide-in panels, comprising:
a top frame defining a plurality of through-slots;
a first side frame defining a first plurality of channels;
a second side frame defining a second plurality of channels;
a bottom frame defining a third plurality of channels; and
a plurality of display panels each displaying a unique decorative element, the plurality of display panels being constructed and arranged to be seated at least partially within the plurality of through-slots, the first plurality of channels, the second plurality of channels, and the third plurality of channels such that a composite display image is formed by the unique decorative elements.

2. A display frame with multiple slide-in panels as in claim 1, wherein the plurality of display panels comprises a first display panel, a second display panel, a third display panel, and a fourth display panel.

3. A display frame with multiple slide-in panels as in claim 2, wherein the first display panel is transparent.

4. A display frame with multiple slide-in panels as in claim 2, wherein the fourth display panel is opaque.

5. A display frame with multiple slide-in panels as in claim 1, wherein the composite display image comprises a three-dimensional shadowbox appearance.

6. A display frame with multiple slide-in panels as in claim 1, wherein each of the unique decorative elements comprises a laser-cut silhouette.

7. A display frame with multiple slide-in panels as in claim 1, wherein each of the unique decorative elements comprises a machine-cut silhouette.

8. A display frame with multiple slide-in panels as in claim 1, wherein each of the unique decorative elements comprise an engraving.

9. A display frame with multiple slide-in panels as in claim 1, wherein each of the unique decorative elements comprise a printed image.

10. A display frame with multiple slide-in panels, comprising:
a generally rectangular top frame defining four through-slots;
a generally rectangular first side frame defining a first set of four channels;
a generally rectangular second side frame defining a second set of four channels;
a generally rectangular bottom frame defining a third set of four channels; and
a plurality of generally rectangular display panels comprising a first, second, third, and fourth display panel, each comprising a unique decorative element, the plurality of display panels being constructed and arranged to be seated at least partially within the plurality of through-slots, the first set of four channels, the second set of four channels, and the third set of four channels such that a composite display image is formed by the unique decorative elements.

11. A display frame with multiple slide-in panels as in claim 10, wherein the first display panel is glass.

12. A display frame with multiple slide-in panels as in claim 10, wherein the fourth display panel is opaque.

13. A display frame with multiple slide-in panels as in claim 10, wherein the composite display image comprises a three-dimensional shadowbox appearance.

14. A display frame with multiple slide-in panels as in claim 10, wherein each of the unique decorative elements comprises a laser-cut decorative silhouette.

15. A display frame with multiple slide-in panels as in claim 10, wherein each of the unique decorative elements comprises a machine-cut decorative silhouette.

16. A display frame with multiple slide-in panels as in claim 10, wherein each of the unique decorative elements comprise an engraving.

17. A display frame with multiple slide-in panels as in claim 10, wherein each of the unique decorative elements comprise a printed image.

18. A display frame with multiple slide-in panels, comprising:
a generally rectangular top frame defining four through-slots;
a generally rectangular first side frame defining a first set of four channels;
a generally rectangular second side frame defining a second set of four channels;
a generally rectangular bottom frame defining a third set of four channels;
a first display panel comprising a first decorative element, the first display panel being removably seated within the first, second, and third set of four channels;
a second display panel comprising a second decorative element, the second display panel being removably seated within the first, second, and third set of four channels;
a third display panel comprising a third decorative element, the third display panel being removably seated within the first, second, and third set of four channels;
a fourth display panel comprising a fourth decorative element, the fourth display panel being removably seated within the first, second, and third set of four channels;
wherein the first, second, third, and fourth decorative elements form a composite display.

19. A display frame with multiple slide-in panels as in claim 18, wherein each of the unique decorative elements comprises at least one of a machine-cut or laser-cut decorative silhouette.

20. A display frame with multiple slide-in panels as in claim 18, wherein each of the unique decorative elements comprises images.
